(19) United States
(12) Patent Application Publication
(10) Pub. No.: US 2007/0018214 A1
(43) Pub. Date: Jan. 25, 2007

(54) Magnesium titanium oxide films

(75) Inventors: Kie Y. Ahn, Chappaqua, NY (US); Leonard Forbes, Corvallis, OR (US)

Correspondence Address: SCHWEGMAN, LUNDBERG, WOESSNER & KLUTH, P.A., P.O. BOX 2938, MINNEAPOLIS, MN, 55402, US

(73) Assignee: Micron Technology, Inc.

(21) Appl. No.: 11/189,075

(22) Filed: Jul. 25, 2005

(51) Int. Cl. H01L 27/108; H01L 21/8242

(52) U.S. Cl. 257/295; 438/785; 438/240; 257/310; 257/632; 438/287; 257/410

(57) ABSTRACT

Embodiments of a magnesium titanium oxide structure on a substrate provide a dielectric for use in a variety of electronic devices. Embodiments of methods of fabricating such a dielectric include forming the magnesium titanium oxide structure by atomic layer deposition.

### TECHNICAL FIELD

This application relates generally to semiconductor devices and device fabrication.

### BACKGROUND

Microwave applications in the communication field are experiencing increasing growth. This growth is spurred by a variety of markets including mobile phones, global positioning systems, and satellite communications. With the increase in microwave applications, demand for monolithic microwave devices with increased capabilities has also increased. However, providing increased capabilities typically is associated with further miniaturization of integrated circuitry. Such further miniaturization, in turn, places additional requirements on microwave dielectric components. These additional requirements may include improved operating characteristics, smaller size, and compatibility with existing circuits. These trends lead to a combination of requirements for dielectric resonators. The dielectric should have a high dielectric constant that may lend itself to possible size miniaturization. The dielectric should have a low dielectric loss (Q=1/tan δ) for a stable resonant frequency. Additionally, the dielectric should have a near-zero temperature coefficient of resonant frequency for temperature stable circuits. Thus, increased miniaturization and other requirements in microwave devices and other microelectronic devices have created the need to provide appropriate dielectric materials together with techniques to fabricate these materials for miniaturization into a variety of microwave components.

### SUMMARY

The abovementioned problems are addressed by the present invention and will be understood by reading and studying the following specification. An embodiment of a method includes forming a magnesium titanium oxide structure by atomic layer deposition. Embodiments include structures for dielectric resonators, capacitors, transistors, memory devices, and electronic systems containing a magnesium titanium oxide structure that may be configured as one or more monolayers, and methods for forming such structures. These and other aspects, embodiments, advantages, and features will become apparent from the following description and the referenced drawings.

### BRIEF DESCRIPTION OF THE DRAWINGS

FIG. 1 depicts an atomic layer deposition system for an embodiment of a method for fabricating a dielectric layer containing a magnesium titanium oxide structure.

FIG. 2 illustrates a flow diagram of elements for an embodiment of a method to form a dielectric layer containing a magnesium titanium oxide film.

FIG. 3 depicts a block diagram of an embodiment of an apparatus having a dielectric resonator on a substrate in which the dielectric resonator includes a magnesium titanium oxide structure.

FIG. 4 shows an embodiment of a configuration of a transistor having a dielectric layer containing a magnesium titanium oxide film.

FIG. 5 shows an embodiment of a configuration of a floating gate transistor having a dielectric layer containing a magnesium titanium oxide film.

FIG. 6 shows an embodiment of a configuration of a capacitor having a dielectric layer containing a magnesium titanium oxide film.

FIG. 7 depicts an embodiment of a dielectric layer including a nanolaminate having at least one layer containing a magnesium titanium oxide film.

FIG. 8 is a simplified diagram for an embodiment in which a magnesium titanium oxide structure is configured in an arrangement of a controller coupled to an electronic device.

FIG. 9 illustrates a diagram for an embodiment of an electronic system having one or more devices containing a magnesium titanium oxide structure.

### DETAILED DESCRIPTION

The following detailed description refers to the accompanying drawings that show, by way of illustration, specific embodiments in which the present invention may be practiced. These embodiments are described in sufficient detail to enable those skilled in the art to practice the present invention. Other embodiments may be utilized and structural, logical, and electrical changes may be made without departing from the scope of the present invention. The various embodiments disclosed herein are not necessarily mutually exclusive, as some disclosed embodiments can be combined with one or more other disclosed embodiments to form new embodiments.

The terms wafer and substrate used in the following description include any structure having an exposed surface with which to form an integrated circuit (IC) structure. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, as well as other semiconductor structures well known to one skilled in the art. The term conductor is understood to generally include n-type and p-type semiconductors, and the term insulator or dielectric is defined generally to include any material that is less electrically conductive than the materials referred to as conductors. The following detailed description is, therefore, not to be taken in a limiting sense, and the scope of the present invention is defined only by the appended claims, along with the full scope of equivalents to which such claims are entitled.

In an embodiment, an electronic apparatus may be formed by a method that includes forming a magnesium titanium oxide structure. The magnesium titanium oxide structure may be structured as one or more monolayers. In an embodiment, magnesium titanium oxide may be formed by atomic layer deposition. The magnesium titanium oxide may be formed as part of a microwave device. In an embodiment, a magnesium titanium oxide structure may be formed as the dielectric for a microwave dielectric resonator. Formation of a magnesium titanium oxide structure for a microwave device is not limited to microwave dielectric resonators, but may be used in various microwave devices and systems. Further, formation of a magnesium titanium oxide structure is not limited to microwave devices and systems, but may be applied to other devices and systems. A dielectric layer may be formed containing magnesium titanium oxide. In an embodiment, the dielectric layer may be formed substantially as a magnesium titanium oxide film. In various embodiments, methods include forming a dielectric layer containing a magnesium titanium oxide film in one or more devices in an integrated circuit. The integrated circuit may be structured as a microwave integrated circuit. The integrated circuit may be structured for application other than as a microwave integrated circuit.

In various embodiments, electronic devices may include a magnesium titanium oxide structure where the magnesium titanium oxide structure is configured as one or more monolayers. Furthermore, the magnesium titanium oxide may be a specific stoichiometric magnesium titanium oxide. The magnesium titanium oxide may be a non-stoichiometric magnesium titanium oxide. The magnesium titanium oxide may be a combination of stoichiometric magnesium titanium oxide and non-stoichiometric magnesium titanium oxide. The expression MgTiOₓ or its equivalent forms may be used to include a stoichiometric magnesium titanium oxide. The expression MgTiOₓ or its equivalent forms may be used to include a non-stoichiometric magnesium titanium oxide. The expression MgTiOₓ or its equivalent forms may be used to include a combination of a stoichiometric magnesium titanium oxide and a non-stoichiometric magnesium titanium oxide. In an embodiment, a magnesium titanium oxide film includes MgTiO₃. The expression MgOₓ may be used to include a stoichiometric magnesium oxide. The expression MgOₓ may be used to include a non-stoichiometric magnesium oxide. The expression MgOₓ may be used to include a combination of a stoichiometric magnesium oxide and a non-stoichiometric magnesium oxide. The expression TiO_{y} may be used to include a stoichiometric titanium oxide. The expression TiO_{y} may be used to include a non-stoichiometric titanium oxide. The expression TiO_{y} may be used to include a combination of a stoichiometric titanium oxide and a non-stoichiometric titanium oxide. In various embodiments, a layer of an oxide compound may be doped with elements other than the elements of the oxide compound.

In an embodiment, a magnesium titanium oxide structure, arranged as one or more monolayers, may have a thickness that ranges from a monolayer to thousands of angstroms or more. The structure may be processed by atomic layer deposition (ALD). A dielectric layer may be formed substantially as a magnesium titanium oxide film. Alternatively, a dielectric layer may include multiple layers with at least one layer being a film of magnesium titanium oxide. Dielectric layers of magnesium titanium oxide offer a material that can provide a relatively high dielectric constant with respect to that of silicon oxide. Such dielectric layers having a relatively high dielectric constant may be used in microwave devices or as a replacement for silicon oxide in capacitors, transistors, memories, and other microelectronic devices and systems.

In an embodiment, a MgTiOₓ dielectric layer is formed using atomic layer deposition. The MgTiOₓ dielectric layer may have a substantially smooth surface relative to other processing techniques. Further, forming such a dielectric layer using atomic layer deposition may control transitions between material layers. Thus, an atomic layer deposited MgTiOₓ dielectric layer can have an engineered transition with a substrate surface.

ALD, also known as atomic layer epitaxy (ALE), is a modification of chemical vapor deposition (CVD) and is also called “alternatively pulsed-CVD.” In ALD, gaseous precursors are introduced one at a time to the substrate surface mounted within a reaction chamber (or reactor). This introduction of the gaseous precursors takes the form of pulses of each gaseous precursor. In a pulse of a precursor gas, the precursor gas is made to flow into a specific area or region for a short period of time. Between the pulses, the reaction chamber may be purged with a gas, where the purging gas may be an inert gas. Between the pulses, the reaction chamber may be evacuated. Between the pulses, the reaction chamber may be purged with a gas and evacuated.

In a chemisorption-saturated ALD (CS-ALD) process, during a first pulsing phase, reaction with the substrate occurs with the precursor saturatively chemisorbed at the substrate surface. Subsequent pulsing with a purging gas removes precursor excess from the reaction chamber.

A second pulsing phase introduces another precursor on the substrate where the growth reaction of the desired film takes place. Subsequent to the film growth reaction, reaction byproducts and precursor excess are purged from the reaction chamber. With favourable precursor chemistry where the precursors adsorb and react with each other aggressively on the substrate, one ALD cycle can be performed in less than one second in properly designed flow type reaction chambers. Typically, precursor pulse times range from about 0.5 sec to about 2 to 3 seconds. Pulse times for purging gases may be significantly larger, for example, pulse times of about 5 to about 30 seconds.

In ALD, the saturation of all the reaction and purging phases makes the growth self-limiting. This self-limiting growth results in large area uniformity and conformality, which has important applications for such cases as planar substrates, deep trenches, and in the processing of porous silicon and high surface area silica and alumina powders. Significantly, ALD provides for controlling film thickness in a straightforward manner by controlling the number of growth cycles.

The precursors used in an ALD process may be gaseous, liquid or solid. However, liquid or solid precursors should be volatile. The vapor pressure should be high enough for effective mass transportation. Also, solid and some liquid precursors may need to be heated inside the ALD system and introduced through heated tubes to the substrates. The necessary vapor pressure should be reached at a temperature below the substrate temperature to avoid the condensation of the precursors on the substrate. Due to the self-limiting growth mechanisms of ALD, relatively low vapor pressure solid precursors can be used, though evaporation rates may vary somewhat during the process because of changes in their surface area.

There are several other characteristics for precursors used in ALD. The precursors should be thermally stable at the substrate temperature, because their decomposition may destroy the surface control and accordingly the advantages of the ALD method that relies on the reaction of the precursor at the substrate surface. A slight decomposition, if slow compared to the ALD growth, may be tolerated.

The precursors should chemisorb on or react with the surface, though the interaction between the precursor and the surface as well as the mechanism for the adsorption is different for different precursors. The molecules at the substrate surface should react aggressively with the second precursor to form the desired solid film. Additionally, precursors should not react with the film to cause etching, and precursors should not dissolve in the film. Using highly reactive precursors in ALD contrasts with the selection of precursors for conventional CVD.

The by-products in the reaction should be gaseous in order to allow their easy removal from the reaction chamber. Further, the by-products should not react or adsorb on the surface.

In a reaction sequence ALD (RS-ALD) process, the self-limiting process sequence involves sequential surface chemical reactions. RS-ALD relies on chemistry between a reactive surface and a reactive molecular precursor. In an RS-ALD process, molecular precursors are pulsed into the ALD reaction chamber separately. A metal precursor reaction at the substrate is typically followed by an inert gas pulse to remove excess precursor and by-products from the reaction chamber prior to pulsing the next precursor of the fabrication sequence.

By RS-ALD, films can be layered in equal metered sequences that may all be essentially identical in chemical kinetics, deposition per cycle, composition, and thickness. RS-ALD sequences generally deposit less than a full layer per cycle. Typically, a deposition or growth rate of about 0.25 to about 2.00 Å per RS-ALD cycle may be realized.

Processing by RS-ALD provides continuity at an interface avoiding poorly defined nucleating regions that are typical for chemical vapor deposition (<20 Å) and physical vapor deposition (<50 Å), conformality over a variety of substrate topologies due to its layer-by-layer deposition technique, use of low temperature and mildly oxidizing processes, lack of dependence on the reaction chamber, growth thickness dependent solely on the number of cycles performed, and ability to engineer multilayer laminate films with a resolution of one to two monolayers. RS-ALD processes allow for deposition control on the order of monolayers and the ability to deposit monolayers of amorphous films.

Herein, a sequence refers to the ALD material formation based on an ALD reaction of a precursor with its reactant precursor. For example, forming magnesium oxide from a bis(cyclopentadienyl)magnesium (CP₂Mg) precursor and H₂O, as its reactant precursor, forms an embodiment of a magnesium/oxygen sequence, which can also be referred to as a magnesium sequence. In various ALD processes that form an oxide or a compound that contains oxygen, a reactant precursor that contains oxygen is used to supply oxygen. Herein, a precursor that contains oxygen and that supplies oxygen to be incorporated in the ALD compound formed, which may be used in an ALD process with precursors supplying the other elements in the ALD compound, is referred to as an oxygen reactant precursor. In the above example, H₂O is an oxygen reactant precursor. A cycle of a sequence may include pulsing a precursor, pulsing a purging gas for the precursor, pulsing a reactant precursor, and pulsing the reactant precursor's purging gas. Further, in forming a layer of a metal species, an ALD sequence may deal with reacting a precursor containing the metal species with a substrate surface. A cycle for such a metal forming sequence may include pulsing a purging gas after pulsing the precursor containing the metal species to deposit the metal. Additionally, deposition of a semiconductor material may be realized in a manner similar to forming a layer of a metal, given the appropriate precursors for the semiconductor material.

In an ALD formation of a compound having more than two elements, a cycle may include a number of sequences to provide the elements of the compound. For example, a cycle for an ALD formation of an ABOₓ compound may include sequentially pulsing a first precursor/a purging gas for the first precursor/a first reactant precursor/the first reactant precursor's purging gas/a second precursor/a purging gas for the second precursor/a second reactant precursor/the second reactant precursor's purging gas, which may be viewed as a cycle having two sequences. In an embodiment, a cycle may include a number of sequences for element A and a different number of sequences for element B. There may be cases in which ALD formation of an ABOₓ compound uses one precursor that contains the elements A and B, such that pulsing the AB containing precursor followed by its reactant precursor onto a substrate may include a reaction that deposits ABOₓ on the substrate to provide an AB/oxygen sequence. A cycle of an AB/oxygen sequence may include pulsing a precursor containing A and B, pulsing a purging gas for the precursor, pulsing a reactant precursor to the A/B precursor, and pulsing a purging gas for the reactant precursor. A cycle may be repeated a number of times to provide a desired thickness of the compound. In an embodiment, a layer of magnesium titanium oxide is formed on a substrate mounted in a reaction chamber using ALD in repetitive magnesium and titanium sequences using precursor gases individually pulsed into the reaction chamber. Alternatively, solid or liquid precursors can be used in an appropriately designed reaction chamber.

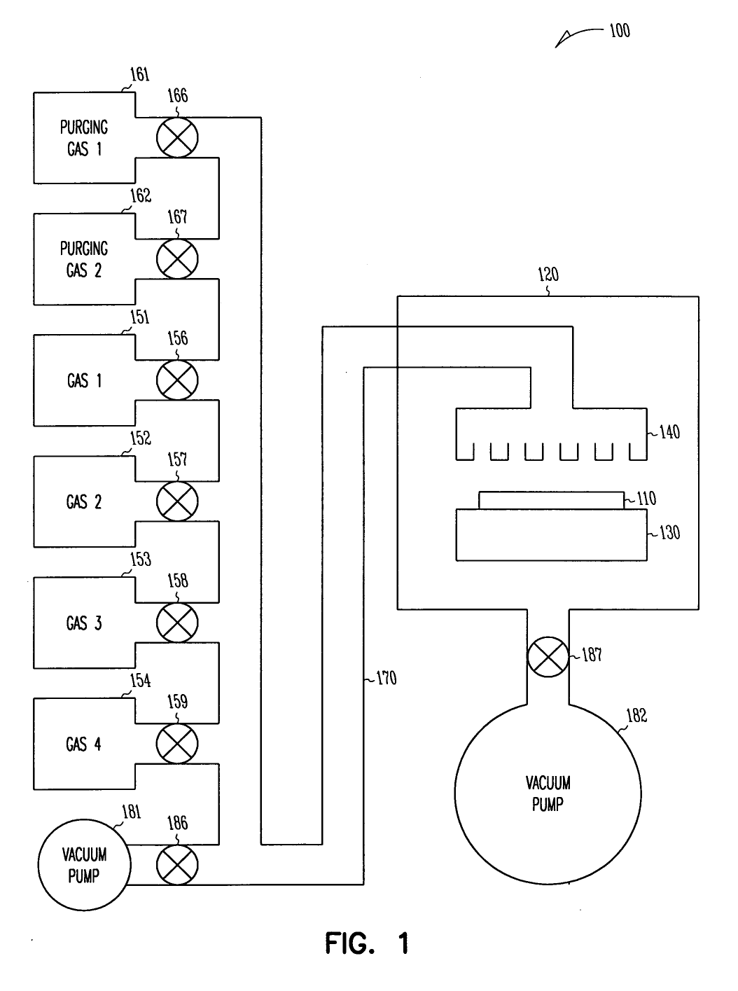

FIG. 1 shows an atomic layer deposition system 100 for an embodiment for processing a magnesium titanium oxide structure. In FIG. 1, a substrate 110 is located inside a reaction chamber 120 of ALD system 100. Also located within the reaction chamber 120 is a heating element 130, which is thermally coupled to substrate 110 to control the substrate temperature. A gas-distribution fixture 140 introduces precursor gases to the substrate 110. Each precursor gas originates from individual gas sources 151-154 whose flow is controlled by mass-flow controllers 156-159, respectively. Gas sources 151-154 may provide a precursor gas by storing the precursor as a gas. Gas sources 151-154 may provide a precursor gas by providing a location and apparatus for evaporating a solid or liquid material to form the selected precursor gas.

Also included in the ALD system are purging gas sources 161, 162, each of which is coupled to mass-flow controllers 166, 167, respectively. Furthermore, additional purging gas sources can be constructed in ALD system 100, one purging gas source for each precursor gas, for example. For a process that uses the same purging gas for multiple precursor gases, fewer purging gas sources are required for ALD system 100. Gas sources 151-154 and purging gas sources 161-162 may be coupled by their associated mass-flow controllers to a common gas line or conduit 170, which is coupled to the gas-distribution fixture 140 inside the reaction chamber 120. Gas conduit 170 is also coupled to vacuum pump, or exhaust pump, 181 by mass-flow controller 186 to remove excess precursor gases, purging gases, and by-product gases from the gas conduit at the end of a purging sequence.

Vacuum pump, or exhaust pump, 182 is coupled by mass-flow controller 187 to remove excess precursor gases, purging gases, and by-product gases from reaction chamber 120 at the end of a purging sequence. For convenience, control displays, mounting apparatus, temperature sensing devices, substrate maneuvering apparatus, and necessary electrical connections as are known to those skilled in the art are not shown in FIG. 1. Though ALD system 100 is well suited for practicing various embodiments, other commercially available ALD systems can be used.

The use, construction and fundamental operation of reaction chambers for deposition of films are understood by those of ordinary skill in the art of semiconductor fabrication. Embodiments may be practiced on a variety of such reaction chambers without undue experimentation. Furthermore, one of ordinary skill in the art will comprehend accompanying detection, measurement, and control techniques in the art of semiconductor fabrication upon reading and studying this disclosure.

The elements of ALD system 100 can be controlled by a computer. To focus on the use of ALD system 100 in the various embodiments, the computer is not shown. Those skilled in the art can appreciate that the individual elements such as pressure control, temperature control, and gas flow within ALD system 100 can be under computer control.

In an embodiment, a method for forming an electronic apparatus includes forming a magnesium titanium oxide structure on a substrate, where the MgTiOₓ structure may be formed as one or more monolayers. The thickness of the MgTiOₓ structure may range from a monolayer to thousands of angstroms or more depending on the application. The MgTiOₓ structure may be formed by atomic layer deposition. In an embodiment, a dielectric region may be formed substantially as a MgTiOₓ film. In an embodiment, a magnesium titanium oxide structure may be engineered with a predetermined amount of magnesium with respect to the total amount of magnesium and titanium in the MgTiOₓ structure. In various non-limiting embodiments, a dielectric region containing a MgTiOₓ structure may be formed as a dielectric resonator in a microwave device, as a dielectric in a capacitor in an integrated circuit, as a dielectric in a capacitor of a dynamic random access memory, as a gate insulator in a silicon complementary metal oxide semiconductor (CMOS) transistor, as a tunnel gate insulator in a flash memory device, as an inter-gate insulator in a flash memory device, as a dielectric region in a non-volatile read only memory (NROM) flash memory, and as a nanolaminate dielectric in a NROM flash memory. Embodiments of a dielectric layer containing a magnesium titanium oxide film may be an integral part of a wide variety of electronic devices in electronic apparatus and systems, according to the teachings herein.

In an embodiment, a method includes forming a dielectric region containing a magnesium titanium oxide structure including forming the magnesium titanium oxide structure by atomic layer deposition. In an ALD process, a magnesium precursor may be pulsed to a substrate. The pulsing of the precursor containing magnesium may provide a material layer having uniform coverage of the desired area of the substrate surface for forming the dielectric layer. Alternatively, coverage of a specific device area may be attained with partial coverage during a particular processing of a sequence. A number of precursors containing magnesium may be used for providing magnesium to the substrate. Subsequent to pulsing the magnesium-containing precursor, a titanium precursor may be pulsed to the substrate. The pulsing of the precursor containing titanium may provide a material layer having uniform coverage of the desired area of the substrate surface for forming the dielectric layer. Alternatively, coverage of a specific device area may be attained with partial coverage during a particular processing of a sequence. A number of precursors containing titanium may be used for providing titanium to the substrate. In an embodiment, the magnesium precursor may be pulsed before the titanium precursor is pulsed. In an embodiment, the titanium precursor may be pulsed before the magnesium precursor is pulsed. Alternatively, magnesium and titanium may be jointly provided to a substrate using precursors that substantially do not react with each other, but provide chemisorption or reaction at the substrate surface and allow subsequent reaction with an oxidant precursor.

In various embodiments, an oxygen reactant precursor may be pulsed after pulsing a purging gas following each pulsing of the titanium precursors and the magnesium precursors. Various oxygen reactant precursors may be used, including, but not limited to, one, or more of water, atomic oxygen, molecular oxygen, ozone, hydrogen peroxide, a water-hydrogen peroxide mixture, alcohol, or nitrous oxide. Alternatively, titanium precursors that contain oxygen may be used such that the titanium sequence does not use an oxygen reactant precursor. Magnesium precursors that contain oxygen may be used such that the magnesium sequence does not use an oxygen reactant precursor.

Structures of MgTiOₓ may be processed over a wide range of temperatures. Low temperature processing may lead to an amorphous structure and have less adverse effects on the substrate and any devices formed prior to the ALD formation of the MgTiOₓ structure. In an embodiment, a MgTiOₓ structure may be formed on a substrate with the substrate maintained at a temperature of about 600° C. or less. The magnesium titanium oxide structure may be formed as an integral component of an electronic device in an integrated circuit.

A magnesium titanium oxide structure may be formed using a number of cycles having various permutations of magnesium/oxide sequences and titanium/oxide sequences. In an embodiment, the magnesium sequences and the titanium sequences are controlled to form the magnesium titanium oxide film with a predetermined amount of titanium with respect to the total amount of titanium and magnesium in the magnesium titanium oxide film. By controlling the content of the titanium and the magnesium in the magnesium titanium oxide structure, a film may be engineered with predetermined electrical characteristics.

In the various embodiments, the thickness of a magnesium titanium oxide structure is related to the number of ALD cycles performed and the growth rate associated with the selected permutations of sequences in the cycles. As can be understood by those skilled in the art, particular effective growth rates for the engineered magnesium titanium oxide structure can be determined during normal initial testing of the ALD system for processing a magnesium titanium oxide dielectric for a given application without undue experimentation.

Either before or after forming a magnesium titanium oxide structure, other dielectric layers such as nitride layers, insulating metal oxide layers, or combinations of nitride and insulating metal oxide layers may be formed as part of a dielectric layer or dielectric stack. Depending on the application, a dielectric stack containing a magnesium titanium oxide film may include a silicon oxide layer. A dielectric layer may be formed as a nanolaminate. An embodiment of a nanolaminate may include a layer of magnesium oxide and a magnesium titanium oxide layer. An embodiment of a nanolaminate may include a layer of titanium oxide and a magnesium titanium oxide layer. An embodiment of a nanolaminate may include a layer of magnesium oxide, a layer of titanium oxide, and a magnesium titanium oxide layer. Alternatively, a dielectric layer may be formed substantially as the magnesium titanium oxide structure.

In various embodiments, the structure of the interface between a dielectric structure and the substrate on which it is disposed is controlled to limit the inclusion of silicon oxide, since a silicon oxide layer would reduce the effective dielectric constant of the dielectric structure. The material composition and properties for an interface layer may be dependent on process conditions and the condition of the substrate before forming the dielectric layer. Though the existence of an interface layer may effectively reduce the dielectric constant associated with the dielectric structure and its substrate, the interface layer, such as a silicon oxide interface layer or other composition interface layer, may improve the interface density, fixed charge density, and channel mobility of a device having this interface layer.

Atomic layer deposition of the individual components of the magnesium titanium oxide structure allows for individual control of each precursor pulsed into the reaction chamber. Thus, each precursor may be pulsed into the reaction chamber for a predetermined period, where the predetermined period may be set separately for each precursor. Additionally, for various embodiments for ALD formation of a MgTiOₓ structure, each precursor may be pulsed into the reaction chamber under separate environmental conditions. The substrate may be maintained at a selected temperature and the reaction chamber maintained at a selected pressure independently for pulsing each precursor. Appropriate temperatures and pressures may be maintained, whether the precursor is a single precursor or a mixture of precursors. During atomic layer deposition, the pulsing of the precursor gases may be separated by purging the reaction chamber with a purging gas following each pulsing of a precursor. In an embodiment, nitrogen gas may be used as the purging gas following the pulsing of each precursor used in a cycle to form a film of magnesium titanium oxide. Additionally, excess gases and byproducts may be removed from the reaction chamber by pulsing purging gases. Excess gases and byproducts may be removed from the reaction chamber by evacuating the reaction chamber. Excess gases and byproducts may be removed from the reaction chamber by pulsing purging gases and evacuating the reaction chamber.

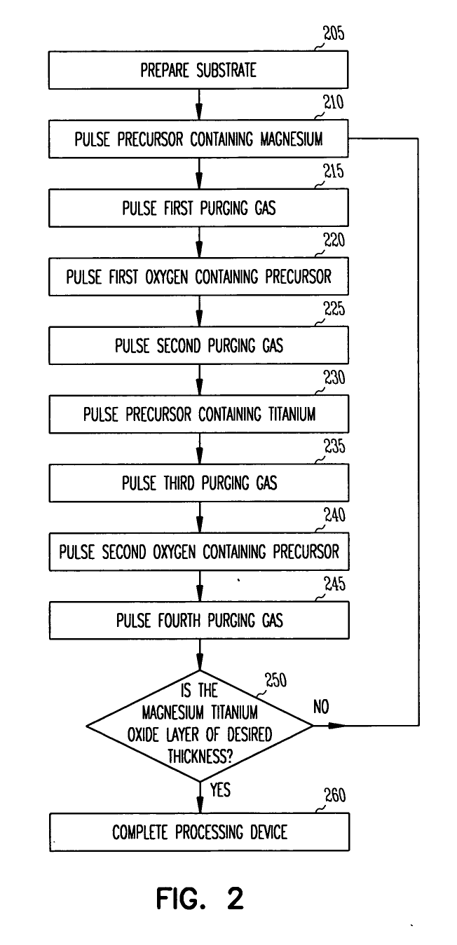

FIG. 2 illustrates a flow diagram of elements for an embodiment of a method to form a dielectric layer containing an atomic layer deposited magnesium titanium oxide film. This embodiment may be implemented with the atomic layer deposition system 100 of FIG. 1. At 205, a substrate 110 is prepared. The substrate used for forming an electronic device such as a transistor is typically a silicon or silicon containing material. In other embodiments, germanium, gallium arsenide, silicon-on-sapphire, sapphire substrates, or other suitable substrates may be used. This preparation process may include cleaning substrate 110 and forming layers and regions of the substrate, such as drains and sources of a metal oxide semiconductor (MOS) transistor, prior to forming a gate dielectric. Alternatively, these active regions may be formed after forming the dielectric layer, depending on the overall fabrication process implemented. In an embodiment, the substrate is cleaned to provide an initial substrate depleted of its native oxide. In an embodiment, the initial substrate is cleaned also to provide a hydrogen-terminated surface. In an embodiment, a silicon substrate undergoes a final hydrofluoric (HF) rinse prior to ALD processing to provide the silicon substrate with a hydrogen-terminated surface without a native silicon oxide layer.

Cleaning immediately preceding atomic layer deposition aids in reducing an occurrence of silicon oxide as an interface between a silicon based substrate and a magnesium titanium oxide dielectric formed using the atomic layer deposition process. The material composition and properties of an interface layer are typically dependent on process conditions and the condition of the substrate before forming the dielectric layer. Though the existence of an interface layer may effectively reduce the dielectric constant associated with the dielectric layer and its substrate, the interface layer, such as a SiO₂ interface layer or other composition interface layer, may improve the interface density, fixed charge density, and channel mobility of a device having this interface layer.

The sequencing of the formation of the regions of an electronic device, such as a transistor, being processed may follow typical sequencing that is generally performed in the particular fabrication of the electronic device as is well known to those skilled in the art. Prior to forming a dielectric layer, masking of substrate regions to be protected during the dielectric formation, as is typically performed in the particular fabrication, may be included in the processing. In an embodiment, the unmasked region may include a body region of a transistor to form a gate dielectric; however, one skilled in the art will recognize that other semiconductor device structures may utilize this process. Alternatively, other sequencing may be used. Additionally, the substrate 110 in its ready-for-processing form is positioned in reaction chamber 120 for ALD processing.

At 210, a precursor containing magnesium is pulsed into reaction chamber 120. The magnesium precursor may be pulsed into reaction chamber 120 through the gas-distribution fixture 140 onto substrate 110. The flow of the magnesium precursor may be controlled by mass-flow controller 156 from gas source 151, where the magnesium precursor is maintained. In an embodiment, a magnesium precursor pulsed into reaction chamber 120 may be Mg(C₂H₅)₂. In an embodiment using a Mg(C₂H₅)₂ precursor, the substrate temperature may be maintained at a temperature ranging from about 350° C. to about 900° C. by heating element 130. In an embodiment, the substrate may be maintained at a temperature in a range from about 500° C. to about 600° C. However, use of individual magnesium precursors is not limited to the temperature ranges of these embodiments. In an embodiment, a magnesium precursor pulsed into reaction chamber 120 may be bis(cyclopentadienyl)magnesium, Mg(C₅H₅)₂. The magnesium precursor reacts with the surface of the substrate 110 in the desired region defined by the unmasked areas of the substrate 110.

At 215, a first purging gas is pulsed into the reaction chamber 120. In an embodiment, an inert gas is used as a purging gas and a carrier gas. The inert gas flow is controlled by mass-flow controller 166 from the purging gas source 161 into the gas conduit 170. Using the inert gas purge avoids overlap of the precursor pulses and possible gas phase reactions. In an embodiment, nitrogen, argon gas, or other inert gases may be used as the purging gas. Following the purge, a first oxygen-containing precursor is pulsed into the reaction chamber 120, at 220.

Water vapor may be used as a precursor acting as an oxygen reactant. The H₂O vapor is pulsed into the reaction chamber 120 through gas conduit 170 from gas source 152 by mass-flow controller 157. The water vapor reacts aggressively at the surface of substrate 110. Other oxygen reactant precursors may be used.

Following the pulsing of the first oxygen-containing precursor, a second purging gas is injected into the reaction chamber 120, at 225. An inert gas may be used to purge the reaction chamber after pulsing each precursor gas in the magnesium/oxygen sequence. In an embodiment, nitrogen, argon gas or other inert gases may be used as the purging gas. Excess precursor gas and reaction by-products may be removed from the system by the purge gas, in conjunction with the exhausting of the reaction chamber 120 using vacuum pump 182 through mass-flow controller 187 and the exhausting of the gas conduit 170 by the vacuum pump 181 through mass-flow controller 186. In an embodiment, the magnesium sequence may be performed a number of times before proceeding to pulse a precursor containing titanium into reaction chamber 120.

At 230, a precursor containing titanium is pulsed into reaction chamber 120. The titanium precursor may be pulsed to the surface of the substrate 110 through gas-distribution fixture 140 from gas source 153 by mass-flow controller 158. In an embodiment, a titanium precursor pulsed may be TiCl₄. In an embodiment using a TiCl₄ precursor, the substrate temperature may be maintained at a temperature ranging from about 100° C. to about 600° C. by heating element 130. In an embodiment using a TiCl₄ precursor, the substrate temperature may be maintained at a temperature ranging from about 500° C. to about 600° C. In an embodiment using a TiCl₄ precursor, the substrate temperature may be maintained at a temperature of about 425° C. However, use of individual titanium precursors is not limited to the temperature ranges of these embodiments. In an embodiment, a titanium precursor pulsed may be TiI₄. In an embodiment, a titanium precursor pulsed may be anhydrous Ti(NO₃)₄. In an embodiment, a titanium precursor pulsed may be titanium isopropoxide, also written as Ti(Oⁱ—Pr)₄. In an embodiment, a titanium precursor pulsed may be Ti(OC₂H₅)₄. The titanium precursor reacts with the surface of the substrate 110 in the desired region defined by the unmasked areas of the substrate 110.

At 235, a third purging gas is introduced into the system. In an embodiment following a titanium precursor, an inert gas may be used as a purging and carrier gas. In various embodiments, nitrogen, argon, or other inert gases may be used as a purging gas. The flow of the third purging gas is controlled by mass-flow controller 167 from the purging gas source 162 into the gas conduit 170 and subsequently into the reaction chamber 120.

At 240, a second oxygen-containing precursor is pulsed into the reaction chamber 120. For a titanium sequence, water vapor may be used as the precursor acting as an oxidizing reactant to interact at the substrate 110. The H₂O vapor is pulsed into the reaction chamber 120 through gas conduit 170 from gas source 152 by mass-flow controller 157. The water vapor reacts aggressively at the surface of substrate 110. Other oxygen reactant precursors may be used.

At 245, a fourth purging gas is injected into the reaction chamber 120. In an embodiment, an inert gas is used as the fourth purging gas to purge the reaction chamber. In various embodiments, nitrogen, argon, or other inert gases may be used as the fourth purging gas. Excess precursor gas and reaction by-products may be removed from the system by the purge gas, in conjunction with the exhausting of the reaction chamber 120 using vacuum pump 182 through mass-flow controller 187 and the exhausting of the gas conduit 170 by the vacuum pump 181 through mass-flow controller 186.

At 250, it is determined whether the magnesium titanium oxide film is of the desired thickness, t. The thickness of a magnesium titanium oxide film after one cycle is determined by the pulsing periods used in the magnesium sequences and the titanium sequences at the given temperatures. Once a set of periods for one cycle is determined, the growth rate for the magnesium titanium oxide film may be set at a value such as N nm/cycle. For a desired magnesium titanium oxide film thickness in an application such as forming a gate dielectric of a MOS transistor, the ALD process should be repeated for t/N cycles.

The desired thickness should be completed after t/N cycles. If less than t/N cycles have been completed, the process starts over at 210 with the pulsing of the precursor containing magnesium. If t/N cycles have completed, no further ALD processing is required and the magnesium titanium oxide film is completed. Once the total number of cycles to form the desired thickness has been completed, the dielectric film containing the magnesium titanium oxide film may optionally be annealed. In an embodiment, the magnesium titanium oxide film may be annealed in a nitrogen atmosphere.

At 260, after forming the magnesium titanium oxide film, processing the device having the dielectric layer containing magnesium titanium oxide film is completed. In an embodiment, completing the device may include further processing of the dielectric layer to include layers of other dielectric materials. In an embodiment, completing the device includes completing the formation of a transistor. In another embodiment, completing the device includes completing the formation of a microwave device. In another embodiment, completing the device includes completing the formation of a capacitor. Alternatively, completing the process includes completing the construction of a memory device having an array with access transistors formed with gate dielectrics containing atomic layer deposited magnesium titanium oxide films. In an embodiment, completing the process includes the formation of an electronic system such as an information handling device that uses electronic devices formed with dielectric films containing an atomic layer deposited magnesium titanium oxide film.

Embodiments for methods having elements similar to the embodiment shown in FIG. 2 may include numerous permutations for forming the magnesium titanium oxide film. In an embodiment, the titanium sequence is conducted before the magnesium sequence. In an embodiment, a magnesium/titanium cycle may include a number, x, of magnesium sequences and a number, y, of titanium sequences. The number of sequences x, y may be selected to engineer the relative amounts of titanium to magnesium. In an embodiment, the number of sequences x and y, along with associated pulsing periods and times, is selected to form a magnesium titanium oxide with substantially equal amounts of magnesium and titanium. In an embodiment, the number of sequences is selected with x=y. In an embodiment, the number of sequences x and y are selected to form a magnesium-rich magnesium titanium oxide. Alternatively, the number of sequences x and y are selected to form a titanium-rich magnesium titanium oxide. In an embodiment, an atomic layer deposition sequence to form a magnesium titanium oxide film includes forming an atomic layer of magnesium oxide followed by forming an atomic layer of titanium oxide. In an embodiment, an atomic layer deposition sequence to form a magnesium titanium oxide film includes forming an atomic layer of titanium oxide followed by forming an atomic layer of magnesium oxide.

In an embodiment, a magnesium titanium oxide structure is formed in a microwave device. The magnesium titanium oxide structure may be configured as one or more monolayers. The magnesium titanium oxide structure may be formed by atomic layer deposition. Magnesium titanium oxide formed in accordance with the teachings of embodiments herein may provide a relatively high dielectric constant (κ>15) that may provide size miniaturization for construction of a microwave device. The dielectric constant for an MgTiOₓ structure may range from the dielectric constant associated with bulk MgO₂ (approximately 9.6) to that associated with bulk TiO₂ (approximately 80), depending on the ratio of magnesium to titanium in the MgTiOₓ structure. Formation of MgTiOₓ as thin layers may be realized with lower dielectric constants due to size effects. Further, occurrence of an interfacial layer between a MgTiOₓ layer and a substrate may lower the dielectric constant associated with the MgTiOₓ layer in an electronic device. In an embodiment, a MgTiO₃ dielectric structure may have a dielectric constant of about 17. In an embodiment, a magnesium titanium oxide structure may provide low dielectric loss for a stable resonant frequency. In addition, embodiments of a magnesium titanium oxide structure may provide a near-zero temperature coefficient of resonant frequency for temperature stable circuits. In an embodiment, a magnesium oxide structure is formed as a dielectric resonator in a microwave device. Formation of a magnesium oxide structure in a microwave device is not limited to dielectric resonators.

FIG. 3 depicts a block diagram of an embodiment of an apparatus 300 having a dielectric resonator 310 on a substrate 305. Dielectric resonator 310 is configured to operate with transistor circuit 330. In an embodiment, a transmission line 320 may be disposed on substrate 305 to magnetically couple dielectric resonator 310 to transistor circuit 330. Dielectric resonator 310 may include a magnesium titanium oxide structure configured as one or more monolayers formed in accordance with the teaching of embodiments herein. The magnesium titanium oxide structure may be formed by atomic layer deposition. Formation of a MgTiOₓ structure according to various embodiments may overcome obstacles to miniaturizing microwave circuits associated with using bulk MgTiO₃ ceramics as dielectric resonators, since bulk MgTiO₃ ceramics have a high sintering temperature.

In various embodiments, a dielectric layer containing a magnesium titanium oxide film may be used in electronic devices as a replacement for a silicon oxide layer. Since magnesium titanium oxide has a dielectric constant that is significantly larger than that of silicon oxide (3.9), a magnesium titanium oxide layer may provide a larger equivalent oxide thickness than a silicon oxide layer having the same physical thickness. An equivalent oxide thickness(t_{eq}) quantifies the electrical properties, such as capacitance, of a dielectric layer in terms of a representative physical thickness. t_{eq} is defined as the thickness of a theoretical SiO₂ layer that would be required to have the same capacitance density as a given dielectric, ignoring leakage current and reliability considerations. For a typical dielectric layer used in an electronic device such as a gate dielectric in a transistor, the capacitance may be determined as one for a parallel plate capacitance: C=κ∈₀A/t, where κ is the dielectric constant, ∈₀ is the permittivity of free space, A is the area of the capacitor, and t is the thickness of the dielectric. The thickness, t, of a material is related to its t_{eq} for a given capacitance, with SiO₂ having a dielectric constant κₒₓ=3.9, as
t=(κ/κₒₓ)t_{eq}=(κ/3.9)t_{eq}.
Thus, materials with a dielectric constant greater than that of SiO₂, 3.9, will have a physical thickness that can be considerably larger than a desired t_{eq}, while providing the desired equivalent oxide thickness. For example, an alternate dielectric material with a dielectric constant of 10 could have a thickness of about 25.6 Å to provide a t_{eq} of 10 Å, not including any depletion/inversion layer effects. Thus, a reduced equivalent oxide thickness for transistors can be realized by using dielectric materials with higher dielectric constants than SiO₂. Such a thicker physical layer aids in fabricating the dielectric layer in electronic devices.

The thinner equivalent oxide thickness required for lower transistor operating voltages and smaller transistor dimensions may be realized by a significant number of materials, but additional fabricating requirements make determining a suitable replacement for SiO₂ difficult. The current view for the microelectronics industry is still for Si based devices. This requires that the gate dielectric employed be grown on a silicon substrate or silicon layer, which places significant constraints on the substitute dielectric material. During the formation of the dielectric on the silicon layer, there exists the possibility that a small layer of SiO₂ could be formed in addition to the desired dielectric. The result would effectively be a dielectric layer consisting of two sublayers in parallel with each other and the silicon layer on which the dielectric is formed. In such a case, the resulting capacitance would be that of two dielectrics in series. As a result, the t_{eq} of the dielectric layer would be the sum of the SiO₂ thickness and a multiplicative factor of the thickness, t, of the dielectric being formed, written as
t_{eq}=t_{SiO}_{₂}+(κₒₓ/κ)t.
Thus, if a SiO₂ layer is formed in the process, the t_{eq} is again limited by a SiO₂ layer. In the event that a barrier layer is formed between the silicon layer and the desired dielectric in which the barrier layer prevents the formation of a SiO₂ layer, the t_{eq} would be limited by the layer with the lowest dielectric constant. However, whether a single dielectric layer with a high dielectric constant or a barrier layer with a higher dielectric constant than SiO₂ is employed, the layer interfacing with the silicon layer should provide a high quality interface to maintain a high channel carrier mobility.

Dielectric layers of magnesium titanium oxide offer a material that can provide a relatively high dielectric constant with respect to that of silicon oxide. Such dielectric layers provide a significantly thinner equivalent oxide thickness compared with a silicon oxide layer having the same physical thickness. Alternatively, such dielectric layers provide a significantly thicker physical thickness than a silicon oxide layer having the same equivalent oxide thickness. This increased physical thickness aids in reducing leakage current. Additionally, various embodiments may be implemented to form transistors, capacitors, memory devices, and other electronic systems including information handling devices.

A transistor 400 as depicted in FIG. 4 may be constructed by forming a source region 420 and a drain region 430 in a silicon based substrate 410, where source and drain regions 420, 430 are separated by a body region 432. Body region 432 defines a channel having a channel length 434. A gate 450 is formed over and contacts gate dielectric 440 disposed on substrate 410. In an embodiment, gate dielectric 440 contains a MgTiOₓ film, in accordance with the teachings of embodiments herein. Gate dielectric 440 may be realized as a dielectric layer formed substantially of a MgTiOₓ. Gate dielectric 440 may be a dielectric layer containing one or more layers of dielectric material in which at least one layer is a MgTiOₓ film. The magnesium titanium oxide film may be a magnesium titanium oxide film structured as monolayers of magnesium titanium oxide.

An interfacial layer 433 may form between body region 432 and gate dielectric 440. In an embodiment, interfacial layer 433 may be limited to a relatively small thickness compared to gate dielectric 440, or to a thickness significantly less than gate dielectric 440 as to be effectively eliminated. Forming the substrate, gate, and the source and drain regions may be performed using standard processes known to those skilled in the art. Additionally, the sequencing of the various elements of the process for forming a transistor may be conducted with standard fabrication processes, as known to those skilled in the art. In an embodiment, gate dielectric 440 may be realized as a gate insulator in a silicon CMOS transistor. Use of such a gate dielectric including a MgTiOₓ film is not limited to silicon based substrates, but may be used with a variety of semiconductor substrates.

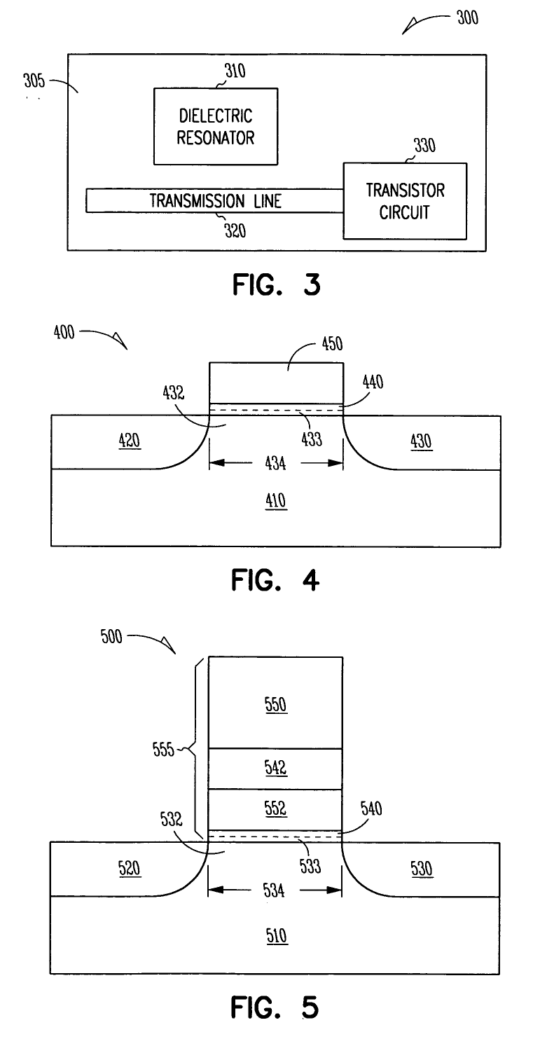

FIG. 5 shows an embodiment of a configuration of a floating gate transistor 500 having an insulating layer containing a magnesium titanium oxide film. Transistor 500 includes a silicon based substrate 510 with a source 520 and a drain 530 separated by a body region 532. Body region 532 between source 520 and drain 530 defines a channel region having a channel length 534. Located above body region 532 is a stack 555 including a gate dielectric 540, a floating gate 552, a floating gate dielectric 542, and a control gate 550. In an embodiment, floating gate 552 is formed over and contacts gate dielectric 540. An interfacial layer 533 may form between body region 532 and gate dielectric 540. In an embodiment, interfacial layer 533 may be limited to a relatively small thickness compared to gate dielectric 540, or to a thickness significantly less than gate dielectric 540 as to be effectively eliminated.

In an embodiment, gate dielectric 540 includes a dielectric containing a MgTiOₓ film structured as one or more monolayers. In an embodiment, gate dielectric 540 includes a dielectric containing an atomic layer deposited MgTiOₓ film. Gate dielectric 540 may be realized as a dielectric layer formed substantially of MgTiOₓ. Gate dielectric 540 may include multiple layers in which at least one layer is substantially magnesium titanium oxide. In an embodiment, gate dielectric 540 may include multiple layers where a substantially MgTiOₓ film contacts body region 532.

In an embodiment, floating gate dielectric 542 includes a dielectric layer having a MgTiOₓ film structured as one or more monolayers. Floating gate dielectric 542 may be realized as a dielectric layer formed substantially of MgTiOₓ.

Floating gate dielectric 542 may include multiple layers in which at least one layer is substantially magnesium titanium oxide. In an embodiment, control gate 550 is formed over and contacts floating gate dielectric 542.

Alternatively, both gate dielectric 540 and floating gate dielectric 542 may be formed as dielectric layers including a MgTiOₓ film. In an embodiment, gate dielectric 540 and floating gate dielectric 542 may be realized by embodiments similar to those described herein, with the remaining elements of the transistor 500 formed using processes known to those skilled in the art.

In an embodiment, gate dielectric 540 forms a tunnel gate insulator and floating gate dielectric 542 forms an inter-gate insulator in flash memory devices. Gate dielectric 540 may include an insulating layer having a MgTiOₓ film structured as one or more monolayers. Floating gate dielectric 542 may include an insulating layer having a MgTiOₓ film structured as one or more monolayers. Gate dielectric 540 and floating gate dielectric 542 may include an insulating layer having a MgTiOₓ film structured as one or more monolayers. Use of dielectric layers configured in various embodiments is not limited to silicon based substrates, but may be used with a variety of semiconductor substrates.

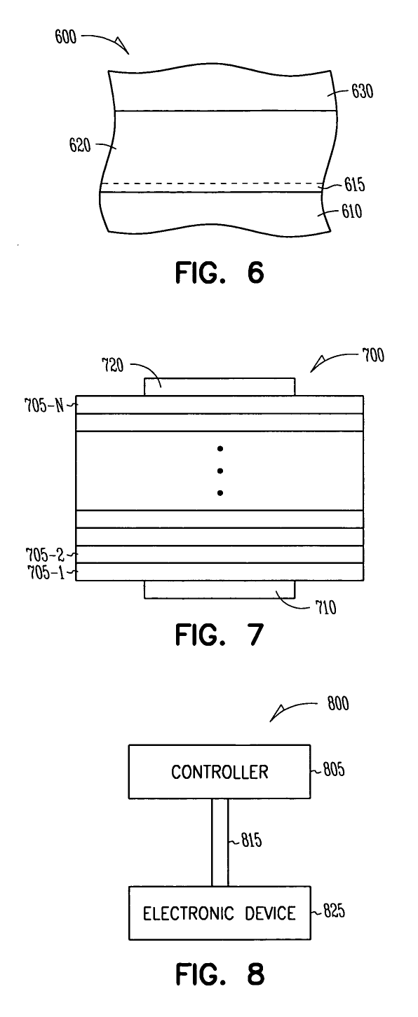

Embodiments of methods for forming dielectric layers containing a magnesium titanium oxide film may also be applied to forming capacitors in various integrated circuits, memory devices, and electronic systems. In an embodiment for a capacitor 600 illustrated in FIG. 6, a method includes forming a first conductive layer 610, forming a dielectric layer 620 containing a magnesium titanium oxide film structured as one or more monolayers on first conductive layer 610, and forming a second conductive layer 630 on dielectric layer 620. Dielectric layer 620, including an insulating layer having a magnesium titanium oxide film, may be formed using various embodiments.

An interfacial layer 615 may form between first conductive layer 610 and dielectric layer 620. In an embodiment, interfacial layer 615 may be limited to a relatively small thickness compared to dielectric layer 620, or to a thickness significantly less than dielectric layer 620 as to be effectively eliminated.

Dielectric layer 620 may be realized as a dielectric layer formed substantially of magnesium titanium oxide. Dielectric layer 620 may include multiple layers in which at least one layer is substantially a MgTiOₓ film. In an embodiment, dielectric layer 620 may include multiple layers where a substantially MgTiOₓ film contacts first conductive layer 610. Embodiments for dielectric layer 620 in a capacitor include, but are not limited to, dielectrics in DRAM capacitors and dielectrics in capacitors in analog, radio frequency (RF), and mixed signal integrated circuits, where mixed signal integrated circuits operate with digital and analog signals.

Various embodiments for a dielectric layer containing a MgTiOₓ film structured as one or more monolayers may provide for enhanced device performance by providing devices with reduced leakage current. The MgTiOₓ film may include atomic layer deposited MgTiOₓ. In an embodiment, such improvements in leakage current characteristics may be attained by forming one or more layers of an atomic layer deposited magnesium titanium oxide in a multi-layer dielectric stack such as a nanolaminate structure. In an embodiment, a nanolaminate includes a MgTiOₓ layer with other dielectric layers including other metal oxides such as magnesium oxide. In an embodiment, a nanolaminate includes a MgTiOₓ layer with other dielectric layers including other metal oxides such as titanium oxide. In an embodiment, a nanolaminate includes a MgTiOₓ layer with other dielectric layers including other metal oxides such as magnesium oxide and titanium oxide. The transition from one layer of the nanolaminate to another layer of the nanolaminate provides further disruption to a tendency for an ordered structure in the nanolaminate stack. The term “nanolaminate” means a composite film of ultra thin layers of two or more materials in a layered stack. Typically, each layer in a nanolaminate has a thickness of an order of magnitude in the nanometer range. Further, each individual material layer of the nanolaminate can have a thickness as low as a monolayer of the material or as high as 20 nanometers. In an embodiment, a MgO_{z}/MgTiOₓ nanolaminate contains alternating layers of magnesium oxide and magnesium titanium oxide. In an embodiment, a TiO_{y}/MgTiOₓ nanolaminate contains alternating layers of titanium oxide and magnesium titanium oxide. In an embodiment, a MgO_{z}/TiO_{y}/MgTiOₓ nanolaminate contains various permutations of magnesium oxide layers, titanium oxide layers, and magnesium titanium oxide layers.

FIG. 7 depicts a nanolaminate structure 700 for an embodiment of a dielectric structure including a magnesium titanium oxide film structured as one or more monolayers. The magnesium titanium oxide film may include atomic layer deposited MgTiOₓ. In an embodiment, nanolaminate structure 700 includes a plurality of layers 705-1, 705-2 to 705-N, where at least one layer contains a MgTiOₓ film formed according to various embodiments. The other layers may be other dielectric layers such as, but not limited to, dielectric metal oxides, insulating nitrides, and insulating oxynitrides. The sequencing of the layers depends on the application. In an embodiment, an atomic layer deposited MgTiOₓ film is the first layer formed on a substrate. In an embodiment, nanolaminate structure 700 contains an atomic layer deposited MgTiOₓ film in contact with conductive contact 710. In an embodiment, nanolaminate structure 700 contains an atomic layer deposited MgTiOₓ film in contact with conductive contact 720. In an embodiment, nanolaminate structure 700 contains one or more atomic layer deposited MgTiOₓ films in contact with conductive contact 710 and conductive contact 720. The effective dielectric constant associated with nanolaminate structure 700 is that attributable to N capacitors in series, where each capacitor has a thickness defined by the thickness of the corresponding layer. By selecting each thickness and the composition of each layer, a nanolaminate structure can be engineered to have a predetermined dielectric constant. Embodiments for structures such as nanolaminate structure 700 may be used as nanolaminate dielectrics in NROM flash memory devices as well as other integrated circuits. In an embodiment, a layer of the nanolaminate structure 700 is used to store charge in the NROM device. The charge storage layer of a nanolaminate structure 700 in an NROM device may be a silicon oxide layer.

Transistors, capacitors, microwave devices, and other microelectronic and optoelectronic devices having dielectric layers containing an atomic layer deposited magnesium titanium oxide film formed according to various embodiments may be implemented into memory devices and electronic systems. Such electronic systems may include information handling devices. Embodiments of these information handling devices may include wireless systems, telecommunication systems, and computers. Further, embodiments of electronic devices having dielectric layers containing a magnesium titanium oxide film structured as one or more monolayers may be realized as integrated circuits.

FIG. 8 illustrates a diagram for an electronic system 800 having one or more devices having a dielectric containing a magnesium titanium oxide structure arranged as one or more monolayers. The magnesium titanium oxide structure may be fabricated by atomic layer deposition according to various embodiments. In an embodiment, such a dielectric is formed substantially as a MgTiOₓ film. Electronic system 800 includes a controller 805, a bus 815, and an electronic device 825, where bus 815 provides conductivity between controller 805 and electronic device 825. In various embodiments, controller 805 may include an embodiment for a dielectric layer having a MgTiOₓ film structured as one or more monolayers. In various embodiments, electronic device 825 may include an embodiment for a dielectric layer having a MgTiOₓ film structured as one or more monolayers. In various embodiments, controller 805 and electronic device 825 may include an embodiment for a dielectric layer having a MgTiOₓ film structured as one or more monolayers. Electronic system 800 may include, but is not limited to, fiber optic systems, electro-optic systems, and information handling systems such as wireless systems, telecommunication systems, and computers.

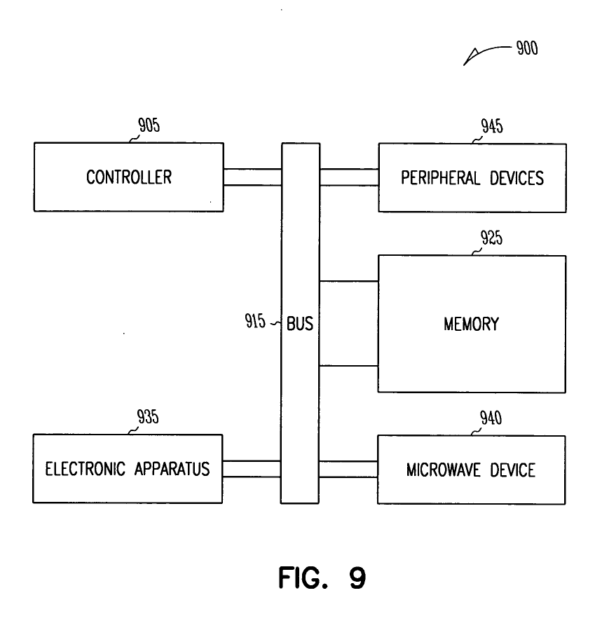

FIG. 9 depicts a diagram of an embodiment of a system 900 having a controller 905 and a memory 925. Controller 905 may include a dielectric layer having a MgTiOₓ film structured as one or more monolayers. Memory 925 may include a dielectric layer having a magnesium titanium oxide film structured as one or more monolayers. Controller 905 and memory 925 may include a dielectric layer having a MgTiOₓ film structured as one or more monolayers. The MgTiOₓ film may be fabricated by atomic layer deposition according to various embodiments. In an embodiment, such a dielectric layer is formed substantially as a MgTiOₓ film.

System 900 also includes an electronic apparatus 935 and a bus 915, where bus 915 provides conductivity between controller 905 and electronic apparatus 935, and between controller 905 and memory 925. Bus 915 may include an address, a data bus, and a control bus, each independently configured. Alternatively, bus 915 may use common conductive lines for providing address, data, control, or various combinations of address, data, and control, the use of which is regulated by controller 905. In an embodiment, electronic apparatus 935 may be additional memory configured in a manner similar to memory 925. An embodiment may include an additional peripheral device or devices 945 coupled to bus 915. In an embodiment, controller 905 is a processor. Any of controller 905, memory 925, bus 915, electronic apparatus 935, and peripheral device or devices 945 may include a dielectric layer including a MgTiOₓ film structured as one or more monolayers. System 900 may include, but is not limited to, information handling devices such as wireless systems, telecommunication systems, and computers.

System 900 may include a microwave device 940 coupled to bus 915. Microwave device 940 may include a magnesium titanium oxide structure. The magnesium titanium oxide structure may be configured as one or more monolayers. The MgTiOₓ structure may be constructed using atomic layer deposition. The thickness of the MgTiOₓ structure may be selected in compliance with a microwave application for the MgTiOₓ structure is being used. Various embodiments provide for the accurate formation of the MgTiOₓ structure to the desired or predetermined thickness.

Peripheral devices 945 may include displays, additional storage memory, or other control devices that may operate in conjunction with controller 905. Alternatively, peripheral devices 945 may include displays, additional storage memory, or other control devices that may operate in conjunction with memory 925. Peripheral devices 945 may include displays, additional storage memory, or other control devices that may operate in conjunction with controller 905 and memory 925.

Memory 925 may be realized as a memory device containing a dielectric layer including a MgTiOₓ film structured as one or more monolayers. The magnesium titanium oxide film may be fabricated by atomic layer deposition according to various embodiments. In an embodiment, such a dielectric layer is formed substantially as a MgTiOₓ film. It will be understood that embodiments are equally applicable to any size and type of memory circuit and are not intended to be limited to a particular type of memory device. Memory types may include a DRAM, SRAM (Static Random Access Memory) or Flash memories. Additionally, the DRAM could be a synchronous DRAM commonly referred to as SGRAM (Synchronous Graphics Random Access Memory), SDRAM (Synchronous Dynamic Random Access Memory), SDRAM II, and DDR SDRAM (Double Data Rate SDRAM), as well as other emerging DRAM technologies.

Although specific embodiments have been illustrated and described herein, it will be appreciated by those of ordinary skill in the art that any arrangement that is calculated to achieve the same purpose may be substituted for the specific embodiments shown. It is to be understood that the above description is intended to be illustrative, and not restrictive, and that the phraseology or terminology employed herein is for the purpose of description and not of limitation. Combinations of the above embodiments and other embodiments will be apparent to those of skill in the art upon studying the above description.

What is claimed is:

1. A method comprising:
forming a magnesium titanium oxide structure on a substrate by atomic layer deposition.

2. The method of claim 1, wherein forming a magnesium titanium oxide structure includes forming a magnesium titanium oxide film with the substrate maintained at a temperature from about 500° C. to about 600° C.

3. The method of claim 1, wherein forming the magnesium titanium oxide structure by atomic layer deposition includes using a precursor containing titanium and a halogen in the atomic layer deposition.

4. The method of claim 3, wherein using a titanium halide precursor in the atomic layer deposition includes using a titanium chloride precursor in the atomic layer deposition.

5. The method of claim 1, wherein forming the magnesium titanium oxide structure by atomic layer deposition includes using a precursor containing titanium and nitrogen in the atomic layer deposition.

6. The method of claim 1, wherein forming the magnesium titanium oxide structure by atomic layer deposition includes using a Ti(OCH(CH₃)₂)₄ precursor in the atomic layer deposition.

7. The method of claim 1, wherein forming the magnesium titanium oxide structure by atomic layer deposition includes using a Ti(OC₂H₅)₄ precursor in the atomic layer deposition.

8. The method of claim 1, wherein forming the magnesium titanium oxide structure by atomic layer deposition includes using a Mg(C₂H₅)₂ precursor in the atomic layer deposition.

9. The method of claim 1, wherein forming the magnesium titanium oxide structure by atomic layer deposition includes using a Mg(C₅H₅)₂ precursor in the atomic layer deposition.

10. The method of claim 1, wherein forming a magnesium titanium oxide structure includes forming an amorphous MgTiOₓ film.

11. The method of claim 1, wherein the method includes forming the magnesium titanium oxide structure as a layer in a dielectric stack.

12. The method of claim 1, wherein forming a magnesium titanium oxide structure includes forming a layer substantially of MgTiO₃.

13. The method of claim 1, wherein the method includes forming the magnesium titanium oxide structure as a dielectric structure in a microwave device.

14. The method of claim 13, wherein forming the magnesium titanium oxide structure as a dielectric structure in a microwave device includes forming a dielectric resonator.

15. The method of claim 1, wherein forming a magnesium titanium oxide structure includes forming a magnesium titanium oxide film as a capacitor dielectric in an integrated circuit.

16. The method of claim 1, wherein forming a magnesium titanium oxide structure includes forming a magnesium titanium oxide film as a capacitor dielectric of a dynamic random access memory.

17. The method of claim 1, wherein forming a magnesium titanium oxide structure includes forming a magnesium titanium oxide layer as a gate insulator in a silicon complementary metal oxide semiconductor transistor.

18. The method of claim 1, wherein forming a magnesium titanium oxide structure includes forming a magnesium titanium oxide layer as a tunnel gate insulator in a flash memory device.

19. The method of claim 1, wherein forming a magnesium titanium oxide structure includes forming a magnesium titanium oxide layer as an inter-gate insulator in a flash memory device.

20. The method of claim 1, wherein forming a magnesium titanium oxide structure includes forming a magnesium titanium oxide layer as a dielectric region in a NROM flash memory.

21. The method of claim 20, wherein forming the magnesium titanium oxide layer includes forming a magnesium titanium oxide film as at least one layer in a nanolaminate.

22. The method of claim 1, wherein forming a magnesium titanium oxide structure includes forming a magnesium titanium oxide film as a dielectric region in a memory and providing contacts to couple the memory to a controller in an electronic system.

23. A method comprising:
forming a dielectric resonator on a substrate, the dielectric resonator having a magnesium titanium oxide structure, including forming the magnesium titanium oxide structure by atomic layer deposition;
forming a transistor circuit on the substrate, the transistor circuit configured to operate with the dielectric resonator.

24. The method of claim 23, wherein the method includes forming a transmission line on the substrate to magnetically couple the dielectric resonator to the transistor circuit.

25. The method of claim 23, wherein forming the magnesium titanium oxide structure by atomic layer deposition includes using a titanium chloride precursor and using a Mg(C₂H₅)₂ precursor in the atomic layer deposition.

26. The method of claim 23, wherein forming the magnesium titanium oxide structure by atomic layer deposition includes using a titanium halide precursor and using a Mg(C₅H₅)₂ precursor in the atomic layer deposition.

27. The method of claim 23, wherein forming the magnesium titanium oxide structure by atomic layer deposition includes maintaining the substrate at a temperature between 500° C. and 600° C.

28. A method comprising:
forming a first conductive layer;
forming a dielectric layer on the first conductive layer, the dielectric layer containing a magnesium titanium oxide film, including forming the magnesium titanium oxide film by atomic layer deposition; and
forming a second conductive layer on the dielectric layer to form a capacitor.

29. The method of claim 28, wherein forming the magnesium titanium oxide film includes forming the magnesium titanium oxide film on a substrate with the substrate maintained at a temperature in the range from 500° C. to 600° C.

30. The method of claim 28, wherein forming a dielectric layer includes forming the dielectric layer substantially of the magnesium titanium oxide film.

31. The method of claim 28, wherein forming the magnesium titanium oxide film includes forming an amorphous magnesium titanium oxide film.

32. The method of claim 28, wherein forming the magnesium titanium oxide film includes forming a layer substantially of MgTiO₃.

33. A method comprising:
forming a source region and a drain region separated by a channel region on a substrate;
forming a dielectric layer above the channel region, the dielectric layer containing a MgTiOₓ film, including forming the MgTiOₓ film by atomic layer deposition; and
forming a gate above the dielectric layer.

34. The method of claim 33, wherein forming a dielectric layer includes forming the dielectric layer substantially of the MgTiOₓ film.

35. The method of claim 33, wherein forming the MgTiOₓ film includes forming a layer substantially of MgTiO₃.

36. The method of claim 33, wherein forming a gate includes forming a control gate.

37. The method of claim 33, wherein forming a gate includes forming a floating gate.

38. The method of claim 33, wherein forming a dielectric layer includes forming the dielectric layer as a gate dielectric contacting the channel region.

39. The method of claim 33, wherein forming a dielectric layer includes forming the dielectric layer as an intergate dielectric.

40. A method comprising:
forming a memory array, including forming a dielectric layer in a cell of the memory array, wherein forming the dielectric layer includes forming a magnesium titanium oxide film by atomic layer deposition.

41. The method of claim 40, wherein forming the magnesium titanium oxide film includes forming the magnesium titanium oxide film on a substrate with the substrate maintained at a temperature ranging from about 500° C. to about 600° C.

42. The method of claim 40, wherein forming a dielectric layer includes forming the dielectric layer substantially of the magnesium titanium oxide film.

43. The method of claim 40, wherein forming the magnesium titanium oxide film by atomic layer deposition includes forming a layer substantially of MgTiO₃.

44. The method of claim 40, wherein forming a memory array includes forming a memory array of a dynamic random access memory.

45. The method of claim 40, wherein forming the dielectric layer includes forming the dielectric layer as a capacitor dielectric in a capacitor of a dynamic random access memory.

46. The method of claim 40, wherein forming the dielectric layer includes forming the dielectric layer as a tunnel gate insulator in a flash memory device.

47. The method of claim 40, wherein forming the dielectric layer includes forming the dielectric layer as an inter-gate insulator in a flash memory device.

48. The method of claim 40, wherein forming the dielectric layer includes forming the dielectric layer as a dielectric region to store charge in a NROM flash memory.

49. The method of claim 40, wherein forming the magnesium titanium oxide structure by atomic layer deposition includes using a titanium halide precursor and using a Mg(C₂H₅)₂ precursor in the atomic layer deposition.

50. The method of claim 40, wherein forming the magnesium titanium oxide structure by atomic layer deposition includes using a titanium halide precursor and using a Mg(C₅H₅)₂ precursor in the atomic layer deposition.

51. A method comprising:
providing a controller, the controller having a magnesium titanium oxide structure, the magnesium titanium oxide structure formed by atomic layer deposition; and
coupling an integrated circuit to the controller.

52. The method of claim 51, wherein providing a controller includes providing a controller having an amorphous magnesium titanium oxide layer.

53. The method of claim 51, wherein coupling an integrated circuit to the controller includes coupling a memory device to the controller.

54. The method of claim 51, wherein providing a controller includes providing a processor.

55. The method of claim 51, wherein coupling an integrated circuit to the controller includes coupling a mixed signal integrated circuit to the controller.

56. The method of claim 51, wherein providing a controller includes providing the controller with the magnesium titanium oxide structure configured in a microwave device.

57. The method of claim 51, wherein the method includes forming an information handling system.

58. A method comprising:
providing a controller; and
coupling an integrated circuit to the controller, the integrated circuit having a magnesium titanium oxide structure, the magnesium titanium oxide structure formed by atomic layer deposition.

59. The method of claim 58, wherein coupling an integrated circuit includes coupling a microwave integrated circuit having the magnesium titanium oxide structure.

60. The method of claim 58, wherein coupling an integrated circuit to the controller includes coupling an integrated circuit including a substantially magnesium titanium oxide structure.

61. The method of claim 58, wherein coupling an integrated circuit to the controller includes coupling a memory device formed as the integrated circuit, the memory device having the magnesium titanium oxide structure.

62. The method of claim 58, wherein providing a controller includes providing a processor.

63. The method of claim 58, wherein the method includes forming an information handling system.

64. The method of claim 63, wherein forming an information handling system includes forming a wireless system.

65. An electronic device comprising:
a dielectric layer on a substrate, the dielectric layer including a magnesium titanium oxide layer structured as one or more monolayers.

66. The electronic device of claim 65, wherein the magnesium titanium oxide layer includes atomic layer deposited magnesium titanium oxide.

67. The electronic device of claim 65, wherein the dielectric layer is substantially the magnesium titanium oxide layer.

68. The electronic device of claim 65, wherein the electronic device includes a microwave circuit including the dielectric layer.

69. The electronic device of claim 65, wherein the electronic device includes a transistor in which the dielectric layer is disposed.

70. The electronic device of claim 65, wherein the electronic device includes a memory in which the dielectric layer is disposed.

71. The electronic device of claim 65, wherein the electronic device includes connections to couple a signal from other components in an electronic system to a conductive layer contacting the dielectric layer.
